(19) United States
(12) Patent Application Publication
(10) Pub. No.: US 2014/0179037 A1
(43) Pub. Date: Jun. 26, 2014

(54) METHOD FOR MANUFCTURING BACKLIGHT MODULE

(71) Applicant: HON HAI PRECISION INDUSTRY CO., LTD., New Taipei (TW)

(72) Inventor: CHIH-CHEN LAI, New Taipei (TW)

(73) Assignee: HON HAI PRECISION INDUSTRY CO., LTD., New Taipei (TW)

(21) Appl. No.: 13/779,754

(22) Filed: Feb. 28, 2013

(30) Foreign Application Priority Data
Dec. 21, 2012 (TW) 101148893

(51) Int. Cl. H01L 33/64

(52) U.S. Cl. CPC H01L 33/641
USPC 438/27

(57) ABSTRACT

A method for manufacturing a backlight module comprises following steps: providing a substrate; providing a flip chip LED and mounting the flip chip LED on a top surface of the substrate to electrically connect with two electrodes via flip chip bonding; providing a frame and mounting the frame on the top surface of the substrate, wherein the frame defines a through hole which receives the flip chip LED therein; and providing a phosphor layer and mounting the phosphor layer on a top end of the frame away from the substrate to make the phosphor layer cover a top end of the through hole and the flip chip LED.

### BACKGROUND

1. Technical Field

The present disclosure relates to backlight modules, and more particularly to a direct-type LED (light emitting diode) backlight module having stable and reliable performance.

2. Description of Related Art

A method for manufacturing a backlight module includes following steps: providing a printed circuit board, a frame and an LED chip, wherein a receiving hole is defined in a central portion of the frame; forming a circuit on an inner surface of the receiving hole, arranging the LED chip in the receiving hole and making the LED chip electrically connect the circuit; two electrodes protruding from a bottom surface of the frame and electrically connecting the printed circuit board; filling glue in the receiving hole to make the glue enclose the LED chip, and drying the glue. Processes for manufacturing the backlight module are complicated and time-consuming. Furthermore, because the LED chip is enclosed by the glue, heat generated from the LED chip is prone to accumulate in the glue, whereby stability and reliability of the backlight module are disadvantageously affected.

Accordingly, it is desirable to provide a method for manufacturing a backlight module which can overcome the described limitations.

### BRIEF DESCRIPTION OF THE DRAWINGS

FIGS. 1-5 are schematic views showing steps of the method for manufacturing a backlight module of the present disclosure.

### DETAILED DESCRIPTION

Embodiments of a method for manufacturing a backlight module, particularly a direct-type LED backlight module will now be described in detail below and with reference to the drawings.

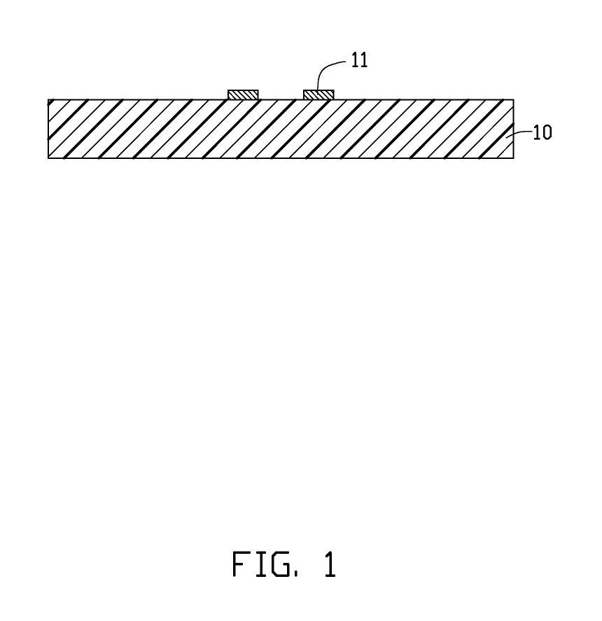

Referring to FIG. 1, the first step is providing a substrate 10, forming a circuit (not shown) and two electrodes 11 on a top surface of the substrate 10. In this embodiment, the electrodes 11 are protruded upwardly from the top surface of the substrate 10 and made of gold. The substrate 10 is made of material having good heat dissipation performance and being electrically insulating, for example, ceramic.

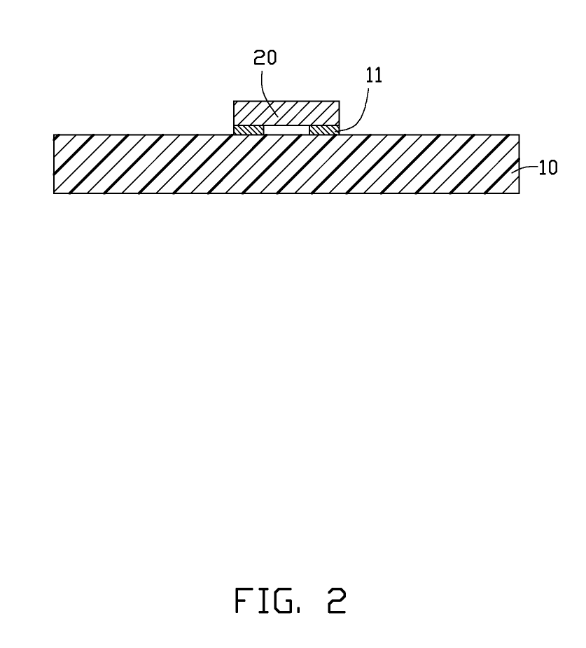

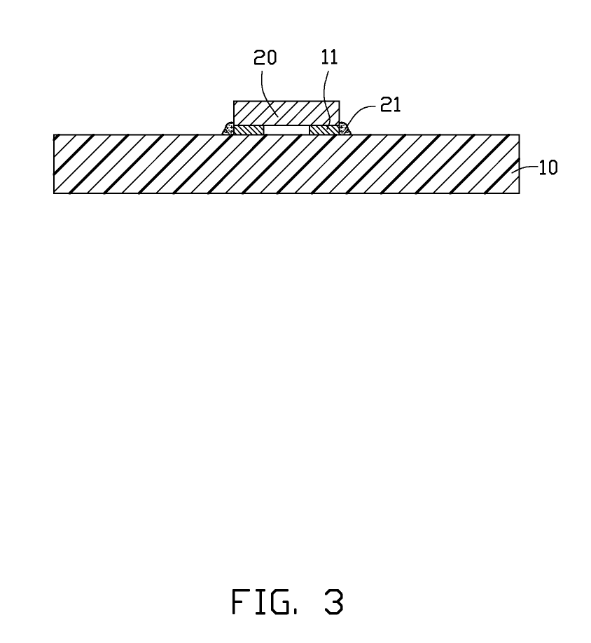

Referring to FIGS. 2-3, the second and third steps are providing a flip chip LED 20 and mounting the flip chip LED 20 on the electrodes 11. A bottom surface of the flip chip 20 has two plane electrodes (not shown). The flip chip LED 20 is located at a top side of the top surface of the substrate 10. The electrodes 11 and the electrodes of the flip chip LED 20 are bonded together. Furthermore, to protect the joints of the electrodes 11 of the substrate 10 and the electrodes of the flip chip LED 20, underfill 21 which is made of electrically insulating material is applied over an external side of each joint.

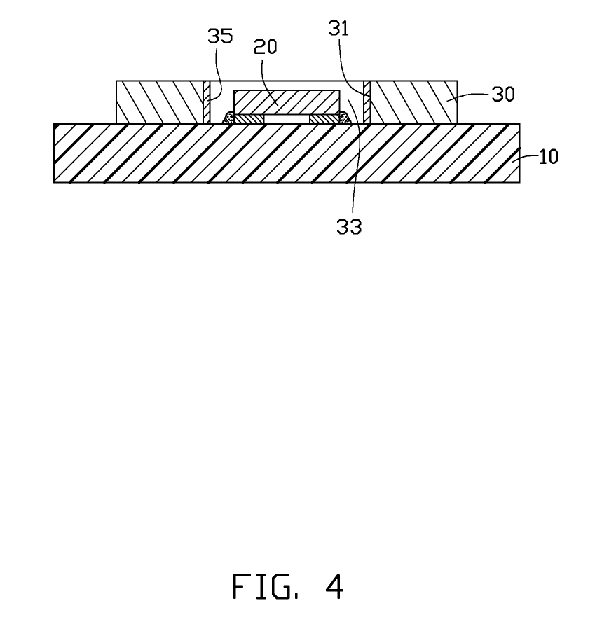

Referring to FIG. 4, the fourth step includes providing a frame 30 and mounting the frame 30 on the top surface of the substrate 10 at a position wherein the flip chip LED 20 is received in the frame 30. The frame 30 is annular, and a through hole 31 is defined at a central portion therein. A bore diameter of the through hole 31 is larger than a diameter of the flip chip LED 20. A bottom surface of the frame 30 is mounted on the top surface of the substrate 10. The flip chip LED 20 is received in the through hole 31 and a gap 33 is defined between an outer periphery of the flip chip LED 20 and an inner surface of the frame 30 defining the through hole 31. A depth of the through hole 31 is equal to or larger than a sum of a height of the flip chip LED 20 and a height of the electrode 11. In this embodiment, the depth of the through hole 31 is larger than the sum of the heights of the clip chip LED 20 and the electrode 11. The frame 30 is opaque and made of material having good heat dissipation performance, for example, aluminum alloy, to dissipate heat absorbed from the flip chip LED 20 rapidly. A reflecting film 35 can be further formed on the inner surface of frame 30 defining the through hole 31 to help reflect more light emitted from the flip chip LED 20 to improve light utilization of the flip chip LED 20. The reflective film 35 can be made of a silver film.

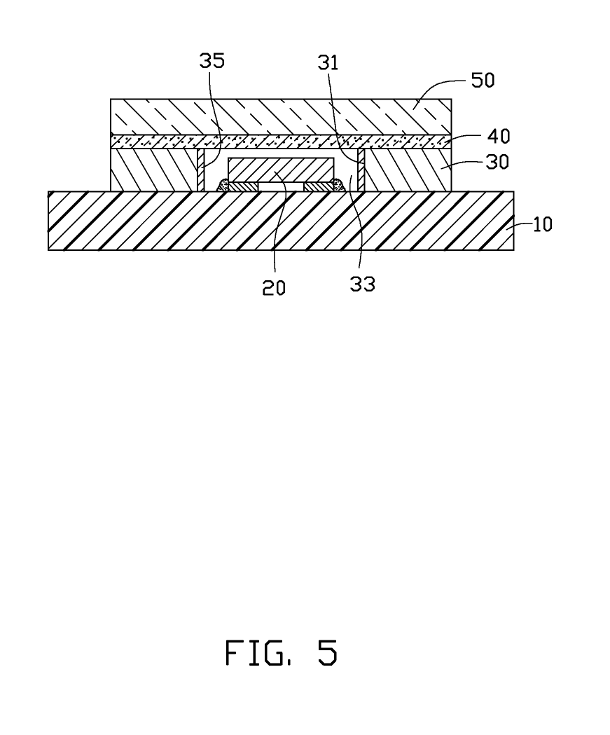

Referring to FIG. 5, the fifth step is providing a phosphor layer 40 and mounting the phosphor layer 40 on a top surface of the frame 30 to make the phosphor layer 40 cover the top end of the through hole 31. In this embodiment, the phosphor layer 40 is an elongated plate and formed by transparent glue and phosphor powder. The phosphor powder and the transparent glue are evenly mixed together. The phosphor layer 40 has a uniform thickness.

The sixth and final step is providing a diffuser 50 and mounting the diffuser 50 on a top of the phosphor layer 40 whereby the diffuser 50 covers the phosphor layer 40. In this state, the backlight module is manufactured completely. In this embodiment, the diffuser 50 is an elongated plate and has a uniform thickness. A size of a bottom surface of the diffuser 50 is equal to a size of a top surface of the phosphor layer 40. The bottom surface of the diffuser 50 is mounted on the top surface of the phosphor layer 40 and entirely covers the top surface of the phosphor layer 40.

In use, light emitted from the flip chip LED 20 radiates to the phosphor layer 40 directly and acts on the phosphor of the phosphor layer 40 to obtain white light. The white light radiates towards the diffuser 50 and is diffused by the diffuser 50, and then evenly radiates out from the diffuser 50.

In this disclosure, the phosphor layer 40 is located over a top of the flip chip LED 20 and spaced from the flip chip LED 20; thus, heat generated from the flip chip LED 20 can be rapidly transferred to the substrate 10 and the frame 30 to be dissipated into the surrounding air to avoid the flip chip LED 20 from overheating. Therefore, the stable and reliable performance of the backlight module is ensured.

It is to be further understood that even though numerous characteristics and advantages of the present embodiments have been set forth in the foregoing description, together with details of the structures and functions of the embodiments, the disclosure is illustrative only, and changes may be made in detail, especially in matters of shape, size, and arrangement of parts within the principles of the disclosure to the full extent indicated by the broad general meaning of the terms in which the appended claims are expressed.

1. A method for manufacturing a backlight module, comprising the following steps:
providing a substrate having two electrodes on a top surface thereof;
providing a flip chip LED (light emitting diode) and mounting the flip chip LED on the top surface of the substrate to have the flip chip LED electrically connect with the two electrodes of the substrate;
providing a frame and mounting the frame on the top surface of the substrate, a through hole defined in the frame, the through hole receiving the flip chip LED therein, the flip chip LED located at a bottom end of the through hole; and
providing a phosphor layer and mounting the phosphor layer on a top end of the frame away from the substrate to make the phosphor layer cover a top end of the through hole and the flip chip LED;
wherein the phosphor layer is an elongated plate and has a uniform thickness, the phosphor layer entirely covers a top end of the through hole, and a space is defined between a bottom surface of the phosphor layer and the top end of the through hole.

2. The method of claim 1, wherein a bore diameter of the through hole is larger than a diameter of the flip chip LED, and the flip chip LED is located at a central part of the through hole to make a gap between a periphery of the flip chip LED and an inner surface of the frame defining the through hole.

3. (canceled)

4. The method of claim 1, wherein the phosphor layer is formed by mixing transparent glue and phosphor powder.

5. The method of claim 4, wherein the phosphor powder and the transparent glue are evenly mixed.

6. (canceled)

7. The method of claim 6ₛ further comprising the following step:
providing a diffuser and mounting the diffuser on the phosphor layer.

8. The method of claim 7, wherein the diffuser entirely covers a top surface of the phosphor layer.

9. The method of claim 8, wherein the diffuser is an elongated plate and has a uniform thickness.

10. The method of claim 1, wherein the two electrodes protrude from the top surface of the substrate and electrically connect a bottom end of the flip chip LED.

11. The method of claim 10, wherein each of the electrodes is made of gold.

12. The method of claim 10, wherein underfill is applied over an external side of each joint of the flip chip LED and the electrodes.

13. The method of claim 1, wherein the frame is opaque and made of material having good heat dissipation performance.

14. The method of claim 1, wherein the substrate is made of material having good heat dissipation performance.
